(19) United States
(12) Patent Application Publication
(10) Pub. No.: US 2025/0006696 A1
(43) Pub. Date: Jan. 2, 2025

(54) SEMICONDUCTOR PACKAGE AND MANUFACTURING METHOD THEREOF

(71) Applicant: Samsung Electronics Co., Ltd., Suwon-si (KR)

(72) Inventors: Yongkoon LEE, Suwon-si (KR); Youngchan KO, Suwon-si (KR); Byung Ho KIM, Suwon-si (KR)

(73) Assignee: Samsung Electronics Co., Ltd., Suwon-si (KR)

(21) Appl. No.: 18/525,724

(22) Filed: Nov. 30, 2023

(30) Foreign Application Priority Data
Jun. 29, 2023 (KR) 10-2023-0084178

(51) Int. Cl. H01L 25/065; H01L 23/00; H01L 23/31; H01L 23/498; H01L 23/522; H01L 25/00

(52) U.S. Cl. CPC H01L 25/0652; H01L 23/3121; H01L 23/49816; H01L 23/49822; H01L 23/49838; H01L 23/5226; H01L 24/08; H01L 24/16; H01L 24/32; H01L 24/73; H01L 25/50; H01L 2224/08225; H01L 2224/16225; H01L 2224/32225; H01L 2224/73204; H01L 2924/1431; H01L 2924/1434; H01L 2924/181

(57) ABSTRACT

A semiconductor package may include a first redistribution layer, bridge dies on an upper surface of the first redistribution layer, a second redistribution layer on the bridge dies and electrically connected to the bridge dies, conductive posts between the first and second redistribution layer, and semiconductor chips on an upper surface of the second redistribution layer. Each bridge die may include connection pads on an upper surface of the bridge dies. A pitch between first connection pads of a first bridge die among the bridge dies may be smaller than a pitch between second connection pads of a second bridge die among the bridge dies. A distance between an upper surface of the first bridge die and a lower surface of the second redistribution layer may be smaller than a distance between an upper surface of the second bridge die and a lower surface of the second redistribution layer.

### CROSS-REFERENCE TO RELATED APPLICATION

This application claims priority to and the benefit of Korean Patent Application No. 10-2023-0084178, filed in the Korean Intellectual Property Office on Jun. 29, 2023, the entire contents of which are incorporated herein by reference.

### BACKGROUND

### (a) Field

The present disclosure relates to a semiconductor package and/or a manufacturing method thereof. Particularly, the present disclosure is suitable for application to a semiconductor package including an interposer in which a bridge die and/or a passive element are embedded.

### (b) Description of the Related Art

Semiconductors are used in various electronic products. Semiconductor packaging is a technique of bundling and combining a plurality of elements including semiconductor chips to be suitable for use in electronic products, and as a result, a semiconductor package is obtained.

A structure of a semiconductor package is also becoming more complex due to high integration and high performance of semiconductor chips. A semiconductor package including two or more semiconductor chips is widely used. In order to provide connection among a plurality of semiconductor chips and to connect the plurality of semiconductor chips to the outside, finer and higher-density of wiring may be required. An interposer realizes a connection between two or more semiconductor chips and a connection between them and an external device (for example, a system board) at a high density.

Meanwhile, as the down-size and high density of the semiconductor chip increases, the number of wires required may increase, and to cope with this, it has been proposed to embed a bridge die in the interposer. The bridge die may include a wire circuit therein, may be embedded in the interposer, and may provide electrical connections between two or more elements mounted on the interposer.

In addition to the bridge die, passive elements may be embedded within the interposer. Typically, the passive element may be a decoupling capacitor.

Conventionally, the bridge die and/or the passive element embedded in the interposer has the same height in a vertical direction. As the integration of two or more semiconductor chips included in a semiconductor package increases and the number of wires significantly increases, connection pads of the bridge die are disposed at a higher density with a finer size. In this case, a height of a pillar that may be formed on each connection pad of the bridge die is also limited.

That is, when the densities of connection pads of bridge dies and/or passive elements embedded in the interposer are different from each other, requirements for the heights of pillars that may be formed on each connection pad of each element are different from each other. In this case, when these elements are disposed at the same height, defects may occur in a subsequent planarization process.

### SUMMARY

Example embodiments of the present disclosure have been made in an effort to provide a semiconductor package and/or a manufacturing method thereof that, by allowing a plurality of elements with connection pads of different densities/pitches to be disposed in an interposer with different heights, may easily set a planarization height in a subsequent planarization process and may limit and/or suppress occurrence of defects.

According to an embodiment of the present disclosure, a semiconductor package may include a first redistribution layer, a plurality of bridge dies on an upper surface of the first redistribution layer, a second redistribution layer on the plurality of bridge dies and electrically connected to the plurality of bridge dies, a plurality of conductive posts between the first redistribution layer and the second redistribution layer, and a plurality of semiconductor chips on an upper surface of the second redistribution layer. Each of the bridge dies may include connection pads on an upper surface of the bridge dies. A pitch between first connection pads of a first bridge die among the plurality of bridge dies may be smaller than a pitch between second connection pads of a second bridge die among the plurality of bridge dies. A distance between an upper surface of the first bridge die and a lower surface of the second redistribution layer may be smaller than a distance between an upper surface of the second bridge die and the lower surface of the second redistribution layer.

According to an embodiment of the present disclosure, a semiconductor package may include a first redistribution layer; a first bridge die on an upper surface of the first redistribution layer; a passive element on the upper surface of the first redistribution layer; a second redistribution layer on the first bridge die and the passive element, the second redistribution layer being electrically connected to the bridge die and the passive element; a plurality of conductive posts between the first redistribution layer and the second redistribution layer; and a plurality of semiconductor chips on an upper surface of the second redistribution layer. The first bridge die may include connection pads on an upper surface of the first bridge die, and the passive element may include connection terminals on an upper surface of the passive element. A pitch between first connection pads of the first bridge die may be smaller than a pitch between the connection terminals of the passive element. A distance between the upper surface of the first bridge die and a lower surface of the second redistribution layer may be smaller than a distance between the upper surface of the passive element and the lower surface of the second redistribution layer.

According to an embodiment of the present disclosure, a manufacturing method of a semiconductor package may include providing a first redistribution layer; providing conductive posts on an upper surface of the first redistribution layer; mounting a first bridge die and a second bridge die on the upper surface of the first redistribution layer, the first bridge die including first connection pads on an upper surface of the first bridge die and first conductive pillars on the first connection pads, the second bridge die including second connection pads on an upper surface of the second bridge die and second conductive pillars on the second connection pads, a pitch between the first conductive pillars being smaller than a pitch between the second conductive pillars, and the upper surface of the first bridge die being higher than the upper surface of the second bridge die in a vertical direction; molding the conductive posts, the first bridge die, and the second bridge die with a mold material; performing planarization by performing a grinding process on a structure including the mold material, the conductive posts, the first conductive pillars, and the second conductive pillars, the grinding process planarizing an upper surface of the structure to have a planarized surface at a grinding target height, the grinding target height being based on both an effective height range of the first conductive pillars according to a pitch between the first conductive pillars and an effective height range of the second conductive pillars according to a pitch between the second conductive pillars; providing a second redistribution layer on the planarized surface of the structure; and mounting a plurality of semiconductor chips on an upper surface of the second redistribution layer.

According to embodiments of the present disclosure, by making the height in the vertical direction different according to the density/pitch of the connection pads of each element embedded in the interposer, it is possible to facilitate setting the planarization height in the planarization process and limit and/or suppress the occurrence of defects.

### BRIEF DESCRIPTION OF THE DRAWINGS

FIG. 1 illustrates an example of a plan view of a semiconductor package according to an example embodiment of the present disclosure.

FIG. 2 illustrates a cross-sectional view of a schematic structure of a semiconductor package according to an example embodiment of the present disclosure.

FIG. 3 illustrates an enlarged view of area M in FIG. 2.

FIG. 4 illustrates a cross-sectional view of a schematic structure of a semiconductor package according to another example embodiment of the present disclosure.

FIG. 5 illustrates an enlarged view of area M in FIG. 4.

FIG. 6 illustrates a cross-sectional view of a schematic structure of a semiconductor package according to another example embodiment of the present disclosure.

FIG. 7 illustrates an enlarged view of area M in FIG. 6.

FIG. 8 illustrates a cross-sectional view of a schematic structure of a semiconductor package according to another example embodiment of the present disclosure.

FIG. 9A to FIG. 9E illustrate a manufacturing method of a semiconductor package according to an example embodiment of the present disclosure.

FIG. 10 illustrates an example of setting a height of an element embedded in an interposer and a planarize height.

### DETAILED DESCRIPTION

The present disclosure will be described more fully hereinafter with reference to the accompanying drawings, in which example embodiments of the disclosure are shown. As those skilled in the art would realize, the described example embodiments may be modified in various different ways, all without departing from the spirit or scope of the present disclosure.

In order to clearly describe aspects the present disclosure, parts or portions that are irrelevant to the description may be omitted, and identical or similar constituent elements throughout the specification may be denoted by the same reference numerals.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

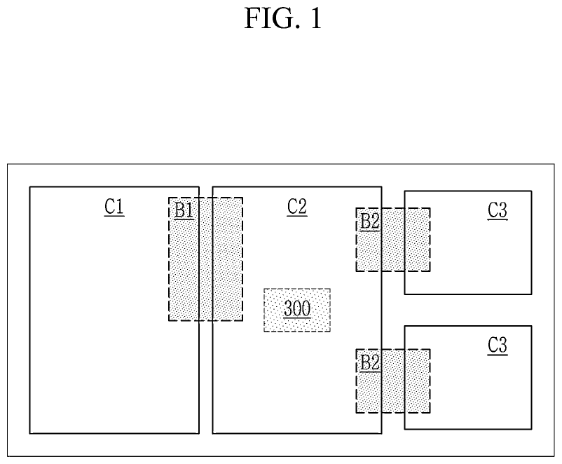

FIG. 1 illustrates an example of a plan view of a semiconductor package according to an example embodiment of the present disclosure.

Referring to FIG. 1, a first semiconductor chip C1, a second semiconductor chip C2, two third semiconductor chips C3, a first bridge die B1, two second bridge dies B2, and a passive element 300 are shown.

These elements are illustrated as examples for explanation, and semiconductor chips may be differently disposed according to design needs, and bridge dies may also be differently disposed according to design needs. In FIG. 1, one passive element 300 is disposed to fully overlap with the second semiconductor chip C2 in a plan view, but a plurality of passive elements may be disposed, or it may be disposed to overlap with another semiconductor chip in a plan view.

The bridge die is a die including a wire pattern that provides an electrical connection between two semiconductor chips. The bridge die may be embedded within the interposer or substrate, and may include a finer wire pattern than the interposer or substrate. Accordingly, the bridge die may provide many electrical connections between highly integrated semiconductor chips.

The bridge die may be disposed to partially overlap with both of two semiconductor chips in a plan view to provide an electrical connection between the two semiconductor chips. As illustrated in FIG. 1, the first bridge die B1 is disposed to partially overlap with both of the first semiconductor chip C1 and the second semiconductor chip C2 in a plan view. Each of the second bridge dies B2 is disposed to partially overlap with the second semiconductor chip C2 and each of the third semiconductor chips C3. Sizes of the first type of bridge die B1 and the second type of bridge dies B2 may vary depending on the number of electrical connection paths and the density of connection pads.

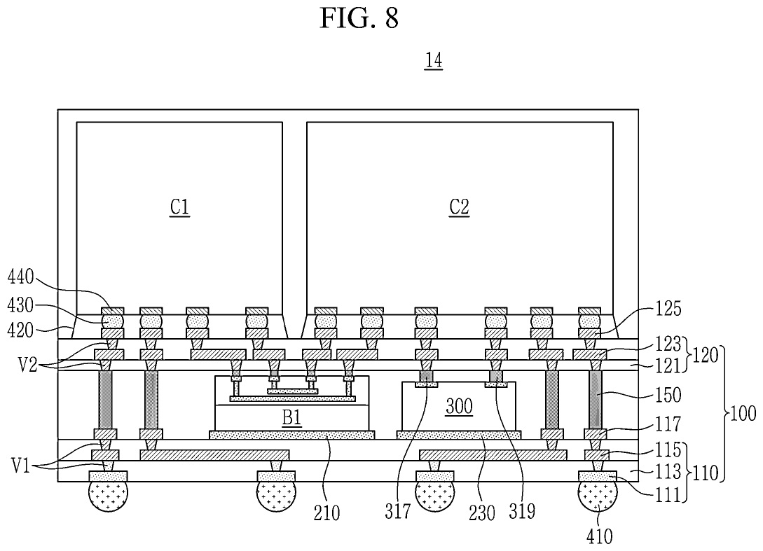

The passive element 300 may be embedded within an interposer or a substrate with a bridge die. The passive element 300 includes connection terminals on the upper surface thereof (see upper terminals 317 in FIG. 8), and these connection terminals are electrically connected to the semiconductor chip through a redistribution layer. The passive element 300 may be, for example, a capacitor, and specifically may be a decoupling capacitor. The passive element 300 may be an inductor or a resistor, and present disclosure is not limited to the type of the passive element 300.

In FIG. 1, one passive element 300 disposed under the second semiconductor chip C2 is shown for convenience, but a plurality of passive elements may be used, and in a plan view, the passive element may be disposed to fully overlap with the first semiconductor chip C1 and/or the third semiconductor chip C3. The number or position of the passive element 300 is not limited in the present disclosure.

The first semiconductor chip C1 and the second semiconductor chip C2 may be a logic chip, and the two third semiconductor chips C3 may be a memory chip, but the present disclosure is not necessarily limited thereto. The first semiconductor chip C1 and the second semiconductor chip C2 may be a buffer chip, a system on chip (SoC), an ASIC chip, an AP chip, a GPU chip, or a CPU chip. The third semiconductor chips C3 may be a chip stack in which a plurality of memory chips are vertically stacked and, may be, for example, a high band memory (HBM) chip.

Since FIG. 1 is only an example diagram for explaining how bridge dies and passive elements are used in a semiconductor package, the present disclosure is not limited to the number, type, and disposition of the semiconductor chips; the number and disposition of the bridge dies; and the number and disposition of the passive elements, shown in FIG. 1.

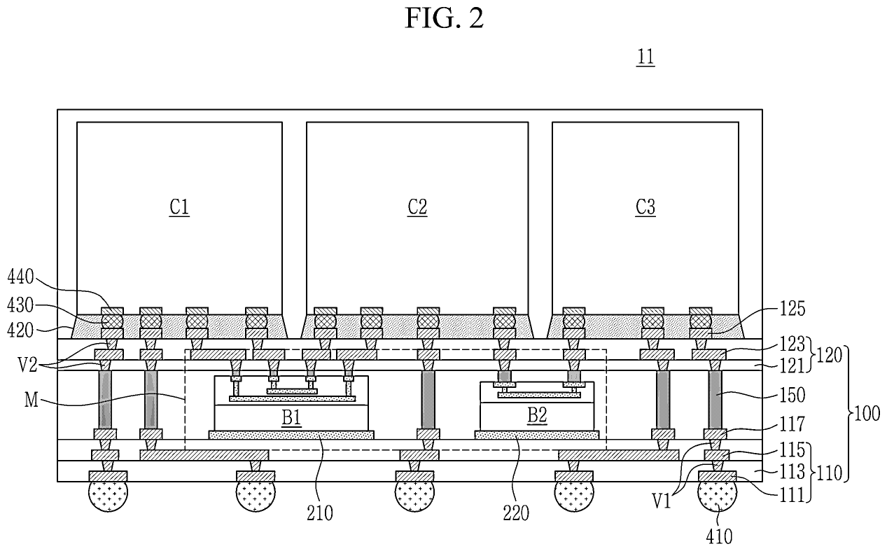

FIG. 2 illustrates a cross-sectional view of a schematic structure of a semiconductor package 11 according to an example embodiment of the present disclosure.

The semiconductor package 11 includes an interposer 100 and a plurality of semiconductor chips C1, C2, and C3 mounted on an upper surface of the interposer 100. Although three semiconductor chips C1, C2, and C3 are shown for better understanding and ease of description, the semiconductor package 11 may include more or fewer semiconductor chips.

The interposer 100 includes a first redistribution layer 110, a first bridge die B1 and a second bridge die B2 mounted on an upper surface of the first redistribution layer 110, a second redistribution layer 120 provided on the first bridge die B1 and the second bridge die B2, and conductive posts 150 disposed between the first redistribution layer 110 and the second redistribution layer 120. A plurality of semiconductor chips C1, C2, and C3 are mounted on an upper surface of the second redistribution layer 120.

The first redistribution layer 110 includes under bump pads 111, a first insulating layer 113, and first redistribution patterns 115. The under bump pads 111 are disposed in the first insulating layer 113, and are exposed to a lower surface of the first insulating layer 113. A bump array 410 is provided on a surface of the exposed under bump pads 111. The bump array 410 is configured to electrically and physically connect the semiconductor package 11 to an external device, for example, a system board. The under bump pads 111 include a conductive metal material such as copper.

The first insulating layer 113 may include, for example, an organic material such as a photosensitive polymer. The photosensitive polymer may include, for example, at least one of photosensitive polyimide, polybenzoxazole, phenol based polymer, and benzocyclobutene based polymer. In the example embodiments of the present disclosure, one layer of the first insulating layer 113 is disclosed for better understanding and ease of description, but two or more layers may be stacked to form the first insulating layer 113.

The first redistribution patterns 115 are electrically connected to the under bump pads 111, and are formed to re-dispose the wire according to design. First vias V1 may connect the first redistribution patterns 115 to the bump pads 111 and first vias V1 may connect the first redistribution patterns 115 to the first pad patterns 117. The first redistribution patterns 115 include a conductive metal material such as copper. In the example embodiments of the present disclosure, for better understanding and ease of description, the first redistribution patterns 115 disposed on one layer are shown, but redistribution patterns disposed on a plurality of layers may be included.

First pad patterns 117 are provided on the first redistribution patterns 115. The first pad patterns 117 are electrically connected to the first redistribution patterns 115 and exposed to the upper side of the first redistribution layer 110. In the present example embodiment, the first pad patterns 117 are not provided in an area in which the first bridge die B1 and the second bridge die B2 are mounted. However, in another example embodiment, when the bridge die includes connection pads for electrical connection on a lower surface thereof, the first pad patterns 117 may also be provided in the mounting area of the corresponding bridge die.

The first bridge die B1, the second bridge die B2, and the conductive posts 150 are provided on the upper surface of the first redistribution layer 110. The first bridge die B1, the second bridge die B2, and the conductive posts 150 are disposed to be spaced apart from each other horizontally. Although their disposition relationship is not limited as described above, the first bridge die B1 and the second bridge die B2 may be disposed on the plurality of semiconductor chips mounted on the upper surface of the interposer 100 in a plan view. The upper surface of the first redistribution layer 110 is flat.

The first bridge die B1 is mounted on the upper surface of the first redistribution layer 110 by a first attachment film 210, and the second bridge die B2 is mounted on the upper surface of the first redistribution layer 110 by a second attachment film 220.

The first attachment film 210 and the second attachment film 220 may include a die attach film (DAF).

Connection pads are provided on the upper surfaces of the first bridge die B1 and the second bridge die B2, and the connection pads are electrically connected to the second redistribution layer 120 through conductive pillars. A detailed structure in which the first bridge die B1 and the second bridge die B2 are connected to the second redistribution layer 120 will be described later.

The conductive posts 150 are provided to be horizontally spaced apart from the first bridge die B1 and the second bridge die B2. The conductive post 150 provides electrical connection between the first redistribution layer 110 and the second redistribution layer 120. The conductive post 150 may be a portion of a path that transmits a signal or a portion of a path that transmits power. For better understanding and ease of description, although conductive posts 150 having the same thickness are shown in the example embodiments of the present disclosure, the conductive post as a signal transmission path and the conductive post as a power supply path may have different thicknesses.

The second redistribution layer 120 is provided on the first bridge die B1, the second bridge die B2, and the conductive posts 150. The lower surface of the second redistribution layer 120 is horizontally flat. The first bridge die B1, the second bridge die B2, and the conductive posts 150 are molded by a mold material, and their surfaces are flattened by a grinding process, and then the second redistribution layer 120 is provided on the flattened surfaces.

The second redistribution layer 120 includes a second insulating layer 121 and second redistribution patterns 123. Similar to the first insulating layer 113, the second insulating layer 121 may include an organic material such as a photosensitive polymer. In the example embodiments of the present disclosure, one layer of the second insulating layer 121 is disclosed for better understanding and ease of description, but two or more layers may be stacked to form the second insulating layer 121.

The second redistribution patterns 123 are configured to be electrically connected to the first bridge die B1, the second bridge die B2, and the conductive posts 150 and to re-dispose a wire. Since the first bridge die B1 and the second bridge die B2 provide electrical connections between the semiconductor chips, the second redistribution patterns 123 of the interposer including the bridge die may have a relatively simpler structure than the second redistribution patterns of the interposer not including the bridge die.

Second pad patterns 125 electrically connected to the second redistribution patterns 123 are provided. The second pad patterns 125 are exposed on the upper surface of the second redistribution layer 120. The second pad patterns 125 are electrically connected to chip pads 440 of the first to third semiconductor chips C1, C2, and C3 through bonding bumps 430. Since the second pad patterns 125 correspond to the chip pads 440 of the semiconductor chips, they are disposed with a higher density than the first pad patterns 117. Second vias V2 may connect the conductive posts 150 to the second redistribution patterns 123 and second vias V2 may connect the second redistribution patterns 123 to the second pad patterns 125.

The first to third semiconductor chips C1, C2, and C3 are mounted on the upper surface of the interposer 100 through the bonding bumps 430, and the gap between the first to third semiconductor chips C1, C2, and C3 and the interposer 100 is filled with a sealing material 420. The sealing material 420 may be an underfill.

The bonding bumps 430 have a much smaller size than the bump array 410 and are disposed with high density. The bonding bumps 430 may be micro bumps or pillar-type bumps. Any technique for mounting a semiconductor chip on an interposer may be applied instead of the bonding bumps 430.

In a non-limiting example embodiment, the thickness of the first redistribution layer 110 may be, for example, 10 μm to 30 μm. The thicknesses of the first bridge die B1 and the second bridge die B2 may be 30 μm to 150 μm. The thicknesses of the first attachment film 210 and the second attachment film 220 may be 3 μm to 25 μm. Since the first bridge die B1 and the second bridge die B2 are used, the thickness of the second redistribution layer 120 is smaller than that of the first redistribution layer 110, and may be, for example, 3 μm to 20 μm.

The first semiconductor chip C1 and the second semiconductor chip C2 may be logic chips, and the third semiconductor chip C3 may be a memory chip. In the present example embodiment, the first bridge die B1 providing electrical connection between the first semiconductor chip C1 and the second semiconductor chip C2 may be required to provide more paths than the second bridge die B2 providing electrical connection between the second semiconductor chip C2 and the third semiconductor chip C3. The first bridge die B1 may need to provide more paths with higher density than the second bridge die B2. In this case, the distance between the upper surface of the first bridge die B1 and the second redistribution layer 120 is smaller than the distance between the upper surface of the second bridge die B2 and the second redistribution layer 120.

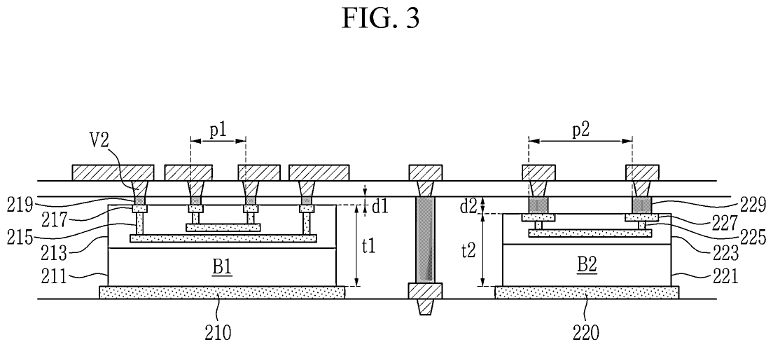

FIG. 3 illustrates an enlarged view of area “M” of FIG. 2. Referring to FIG. 3, a difference in height in a vertical direction between the upper surface of the first bridge die B1 and the upper surface of the second bridge die B2 will be described.

Referring to FIG. 3, the first bridge die B1 is mounted on the upper surface of the first redistribution layer 110 by the first attachment film 210, and the second bridge die B2 is mounted on the upper surface of the first redistribution layer 110 by the second attachment film 220.

The first bridge die B1 includes a first silicon layer 211 and a first connection layer 213. The first connection layer 213 includes first connection pads 217 exposed on an upper surface thereof and first connection patterns 215 connecting the first connection pads 217 according to design.

The second bridge die B2 includes a second silicon layer 221 and a second connection layer 223. The second connection layer 223 includes second connection pads 227 exposed on an upper surface thereof and second connection patterns 225 connecting the second connection pads 227 according to design.

The first connection pads 217 are electrically connected to the second redistribution layer 120 through first conductive pillars 219, and the second connection pads 227 are electrically connected to the second redistribution layer 120 through second conductive pillars 229. Second vias V2 may connect the first connection pillars 219 to the second redistribution layer 120 and second vias V2 may connect the second conductive pillars 229 to the second redistribution layer 120.

The density of the first connection pads 217 is higher than that of the second connection pads 227 so that the first bridge die B1 provides more paths than the second bridge die B2. A pitch p1 between the first conductive pillars 219 provided on the first connection pads 217 is smaller than a pitch p2 between the second conductive pillars 229 provided on the second connection pads 227. To limit and/or suppress signal interference, the first conductive pillars 219 are thinner than the second conductive pillars 229. That is, the thickness of the first conductive pillars 219 is smaller than that of the second conductive pillars 229.

The first conductive pillars 219 and the second conductive pillars 229 may be a post type or a bump type. The shape of the conductive pillars is not limited.

For stability in the manufacturing process, as the thickness of the pillar decreases, the maximum height of the pillar is limited. For example, when the pitch is 55 μm, the appropriate thickness of the pillar is 38 μm, and the maximum height of the pillar is 35 μm. When the pitch is 45 μm, the appropriate thickness of the pillar is 28 μm, and the maximum height of the pillar is 25 μm. When the pitch is 25 μm, the appropriate thickness of the pillar is 17 μm, and the maximum height of the pillar is 16 μm. As such, when the pitches of the pillars are different, the maximum heights of the pillars are also different.

In a non-limiting example embodiment, when the pitch of the first conductive pillars 219 provided on the first connection pads 217 of the first bridge die B1 is 25 μm and when the pitch of the second conductive pillars 229 provided on the second connection pads 227 of the second bridge die B2 is 55 μm, the maximum height of the first conductive pillars 219 is 16 μm, while the maximum height of the second conductive pillars 229 is 35 μm. The difference between the maximum height of the first conductive pillars 219 and the maximum height of the second conductive pillars 229 is 19 μm.

Meanwhile, minimum heights of the first conductive pillars 219 and the second conductive pillars 229 may be set. The first redistribution layer 110 is assumed to have a flat upper surface. The first conductive pillars 219 of the first bridge die B1, the second conductive pillars 229 of the second bridge die B2, and the conductive posts 150 are planarized by a grinding process before the second redistribution layer 120 is formed thereon. The second redistribution layer 120 is formed on the surface planarized by the grinding process. Total thickness variation (TTV) is an important parameter that determines the quality of semiconductor products. The TTV is expressed in microns or mils. When the target height of the surface to be flattened by the grinding process is set, considering the TTV of the first redistribution layer 110, the TTV generated by the grinding process, the distribution of the conductive posts 150, and the distribution of the first and second conductive pillars 219 and 229, minimum heights of the first and second conductive pillars 219 and 229 must be determined, and the target height must be higher than the minimum height to improve the TTV risk.

In the example embodiments of the present disclosure, the upper surface of the first bridge die B1 having a relatively small pitch is at a higher position in the vertical direction than the upper surface of the second bridge die B2 having a relatively large pitch. Accordingly, the target height may be set between the minimum height and the maximum height of the first conductive pillars 219 determined according to the pitch of the first conductive pillars 219 connected to the first bridge die B1. Since the upper surface of the first bridge die B1 is at a position higher in the vertical direction than the upper surface of the second bridge die B2, it is easy to set a target height for TTV risk improvement for the first conductive pillars 219 with a sufficient margin. If the upper surface of the first bridge die B1 has the same vertical height as the upper surface of the second bridge die B2, the target height considering the pitch of the first conductive pillars 219 connected to the first bridge die B1 may be outside the range between the minimum height and the maximum height of the second conductive pillars 229 connected to the second bridge die B2, or a sufficient margin thereof may not be ensured.

In the example embodiments of the present disclosure, a distance d1 between the upper surface of the first bridge die B1 and the lower surface of the second redistribution layer 120 is smaller than a distance d2 between the upper surface of the second bridge die B2 and the lower surface of the second redistribution layer 120. That is, d1<d2. To generate this difference in distance, in the present example embodiment, a thickness t1 of the first bridge die B1 is greater than a thickness t2 of the second bridge die B2. That is, t1>t2. The first attachment film 210 and the second attachment film 220 have the same thickness.

The thicknesses t1 and t2 of the bridge dies may be thicknesses including a silicon layer and a connection layer. Since the first bridge die B1 and the second bridge die B2 are mounted on the upper surface of the flat first redistribution layer 110, the upper surface of the first bridge die B1 having a larger thickness is closer to the lower surface of the second redistribution layer 120 than the upper surface of the second bridge die B2 having a smaller thickness.

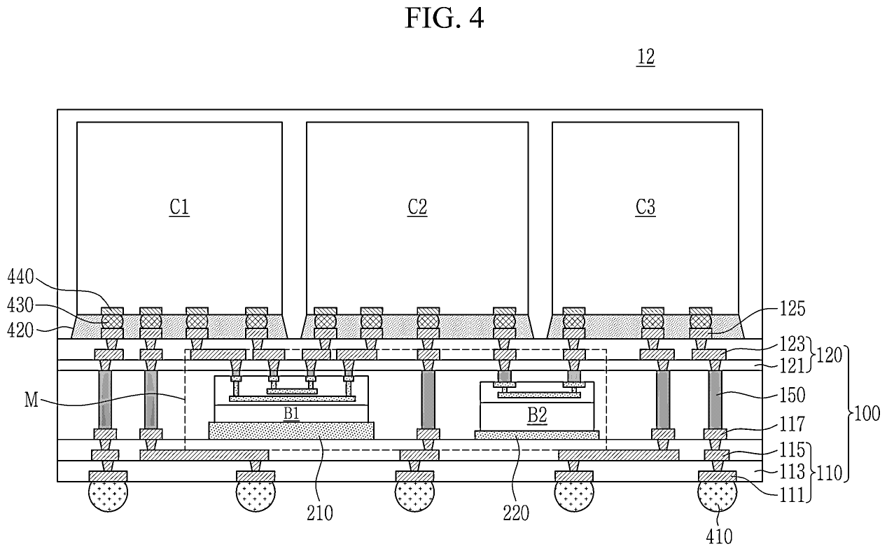

FIG. 4 illustrates a cross-sectional view of a schematic structure of a semiconductor package according to another example embodiment of the present disclosure.

A semiconductor package 12 includes an interposer 100 and a plurality of semiconductor chips C1, C2, and C3 mounted on an upper surface of the interposer 100. The interposer 100 includes a first redistribution layer 110, a second redistribution layer 120, a plurality of bridge dies B1 and B2, and conductive posts 150.

For the first redistribution layer 110, the second redistribution layer 120, the conductive posts 150, the bump array 410, and the first to third semiconductor chips C1, C2, and C3, the example embodiment described above with reference to FIG. 2 may be referred to, so that repeated descriptions will be omitted and the present example embodiment will be described focusing on the differences.

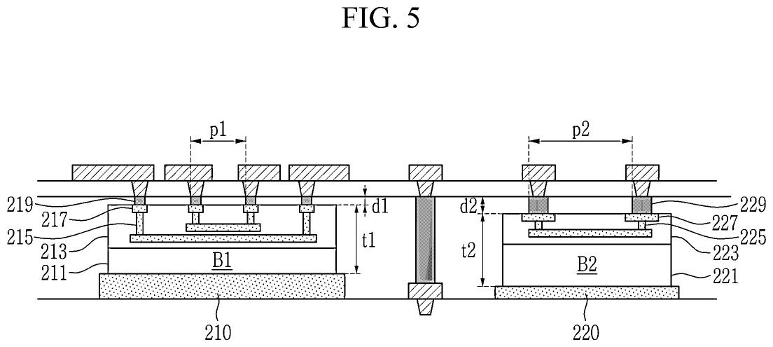

The first bridge die B1 and the second bridge die B2 have the same thickness, but the first attachment film 210 and the second attachment film 220 have different thicknesses. In more detail, it will be described with reference to FIG. 5.

FIG. 5 illustrates an enlarged view of area M in FIG. 4. As shown in FIG. 5, the thickness t1 of the first bridge die B1 is the same as the thickness t2 of the second bridge die B2. That is, t1=t2. On the other hand, the thickness of the first attachment film 210 is greater than the thickness of the second attachment film 220. Accordingly, the upper surface of the first bridge die B1 is closer to the lower surface of the second redistribution layer 120 than the upper surface of the second bridge die B2. That is, d1<d2.

In some example embodiments, the first attachment film 210 and the second attachment film 220 may have a thickness ranging from 3 μm to 25 μm. That is, since the first attachment film 210 has a maximum thickness of 25 μm and the second attachment film 220 has a minimum thickness of 3 μm, a difference in thickness of up to 22 μm may occur, and a difference in thickness may be adjusted within a range of 22 μm or less.

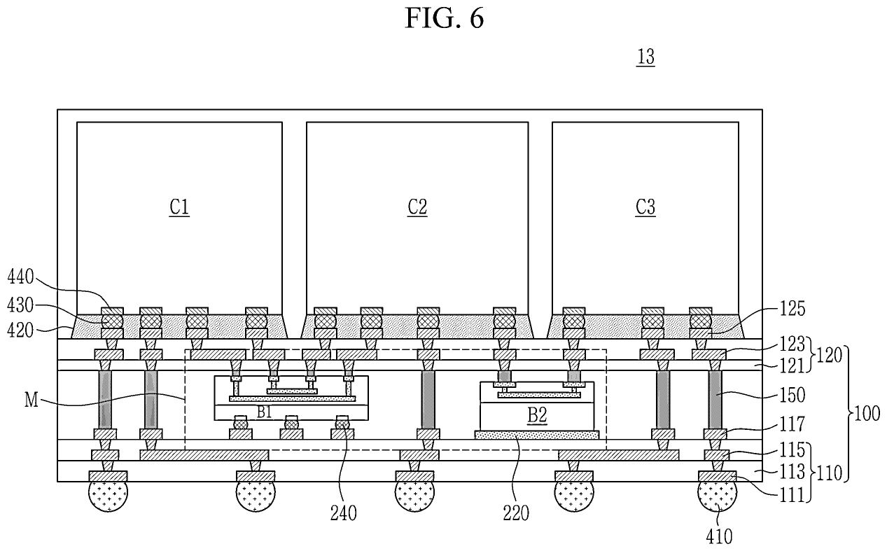

FIG. 6 illustrates a cross-sectional view of a schematic structure of a semiconductor package according to another example embodiment of the present disclosure.

A semiconductor package 13 includes an interposer 100 and a plurality of semiconductor chips C1, C2, and C3 mounted on an upper surface of the interposer 100. The interposer 100 includes a first redistribution layer 110, a second redistribution layer 120, a plurality of bridge dies B1 and B2, and conductive posts 150.

For the first redistribution layer 110, the second redistribution layer 120, the conductive posts 150, the bump array 410, and the first to third semiconductor chips C1, C2, and C3, the example embodiment described above with reference to FIG. 2 may be referred to, so that repeated descriptions are omitted and the present example embodiment will be described focusing on the differences.

The first bridge die B1 is mounted on the upper surface of the first redistribution layer 110 by the solder bumps 240, and the second bridge die B2 is mounted on the upper surface of the first redistribution layer 110 by the second attachment film 220.

The upper surface of the first bridge die B1 is disposed closer to the lower surface of the second redistribution layer 120 than the upper surface of the second bridge die B2.

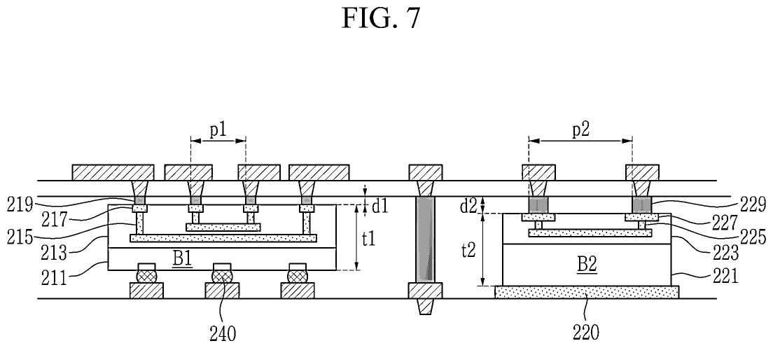

In more detail, it will be described with reference to FIG. 7. FIG. 7 illustrates an enlarged view of area M in FIG. 6.

In FIG. 6 and FIG. 7, the thickness t1 of the first bridge die B1 is shown to be smaller than the thickness t2 of the second bridge die B2, but this is only for convenience of description and does not limit the present example embodiment. The thickness t1 of the first bridge die B1 and the thickness t2 of the second bridge die B2 are determined in consideration of the gap between the upper surface of the first redistribution layer 110 by solder bumps 240 and the lower surface of the first bridge die B1 and the thickness of the second attachment film 220, respectively.

The solder bumps 240 have various sizes. A fine-pitch bump has a size of 50 μm, a micro bump has a size of 20 μm to 30 μm, a copper pillar bump has a size of 15 μm to 20 μm, and an indium bump has a size of 5 μm. Depending on the height to be set, bumps of an appropriate size may be employed as the solder bumps 240. In addition, the second attachment film 220 may have a thickness in the range of 3 μm to 25 μm.

A gap between the upper surface of the first redistribution layer 110 and the lower surface of the first bridge die B1 may be determined according to the size of the solder bumps 240. The size of the solder bumps 240, the thickness of the first bridge die B1, the thickness of the second attachment film 220, and the thickness of the second bridge die B2 are respectively determined so that the sum of this gap and the thickness of the first bridge die B1 is greater than the sum of the thickness of the second attachment film 220 and the thickness of the second bridge die B2. Accordingly, the upper surface of the first bridge die B1 is closer to the lower surface of the second redistribution layer 120 than the upper surface of the second bridge die B2. That is, d1<d2.

FIG. 8 illustrates a cross-sectional view of a schematic structure of a semiconductor package according to another example embodiment of the present disclosure.

A semiconductor package 14 includes an interposer 100 and a plurality of semiconductor chips C1 and C2 mounted on an upper surface of the interposer 100. The interposer 100 includes a first redistribution layer 110, a second redistribution layer 120, a first bridge die B1, and a passive element 300, conductive posts 150.

For the first redistribution layer 110, the second redistribution layer 120, the conductive posts 150, the bump array 410, and the plurality of semiconductor chips C1 and C2, the example embodiment described above with reference to FIG. 2 may be referred to, so that repeated descriptions are omitted and the present example embodiment will be described focusing on the differences.

The first bridge die B1 is mounted on the upper surface of the first redistribution layer 110 by the first attachment film 210, and the passive element 300 is mounted on the upper surface of the first redistribution layer 110 by the third attachment film 230.

When viewed in a plan view, the first bridge die B1 is disposed to partially overlap with both of the first semiconductor chip C1 and the second semiconductor chip C2, and the passive element 300 is disposed to fully overlap with the second semiconductor chip C2.

The passive element 300 may be a capacitor, but may also be an inductor or a resistor. The passive element 300, in general, has relatively lower density connection terminals than the bridge die. The connection terminals 317 are electrically connected to the second redistribution layer 120 through conductive pillars 319.

In the present example embodiment, the thickness of the first bridge die B1 is greater than the thickness of the passive element 300. Accordingly, the upper surface of the first bridge die B1 is disposed closer to the lower surface of the second redistribution layer 120 than the upper surface of the passive element 300.

Although not shown, in order to dispose the upper surface of the first bridge die B1 closer to the lower surface of the second redistribution layer 120 than the upper surface of the passive element 300, the first attachment film 210 having a greater thickness than the third attachment film 230 may be used. In another example, the first bridge die B1 may be mounted on the upper surface of the first redistribution layer 110 by the solder bumps, and the passive element 300 may be mounted on the upper surface of the first redistribution layer 110 by the third attachment film 230.

When the thickness of the first attachment film 210 and the thickness of the third attachment film 230 are appropriately set, it will be easily understood by those skilled in the art that the thickness of the first bridge die B1 and the thickness of the passive element 300 may be determined accordingly.

In the above example embodiments, although the example embodiments of the semiconductor package 11, 12, and 13 including a plurality of bridge dies and the example embodiment of the semiconductor package 14 including a bridge die and passive elements have been disclosed, a semiconductor package including a plurality of bridge dies and passive elements may be provided.

In the example embodiment, the first bridge die B1, the second bridge die B2, and the passive element 300 may be mounted on the upper surface of the same first redistribution layer 110. The pitch of the first conductive pillars 219 of the first bridge die B1 may be the smallest, the pitch of the conductive pillars provided on the connection pads of the passive element 300 may be the largest, and the pitch of the second conductive pillars 229 of the second bridge die B2 may have an intermediate value. In this case, the upper surface of the first bridge die B1 may be closest to the lower surface of the second redistribution layer 120, the upper surface of the passive element 300 may be farthest from the lower surface of the second redistribution layer, and the distance between the upper surface of the second bridge die B2 and the lower surface of the second redistribution layer 120 may have an intermediate value. To implement this, it is possible to set different thicknesses of the first bridge die B1, the second bridge die B2, and the passive element 300, respectively. Alternatively, it is possible to differently set the thicknesses of the first attachment film 210, the second attachment film 220, and the third attachment film 230.

When a plurality of bridge dies and a plurality of passive elements are embedded in the interposer, it is possible to set the distance between the upper surface of each element and the lower surface of the second redistribution layer 120 based on the pitch of the pillars/bumps for each element to be electrically connected to the second redistribution layer 120. The smaller the pitch, the shorter the distance to the second redistribution layer is set.

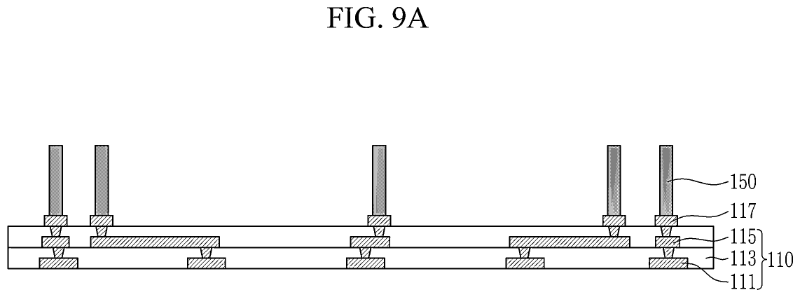

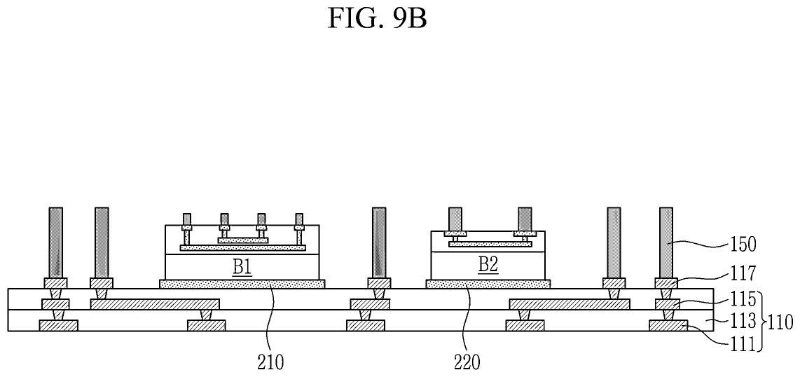

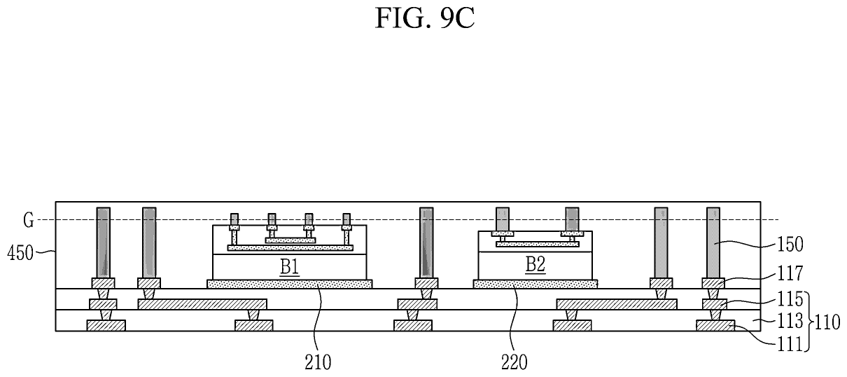

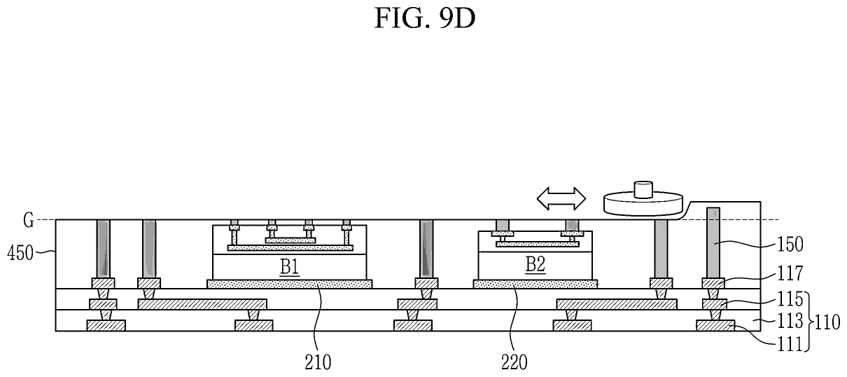

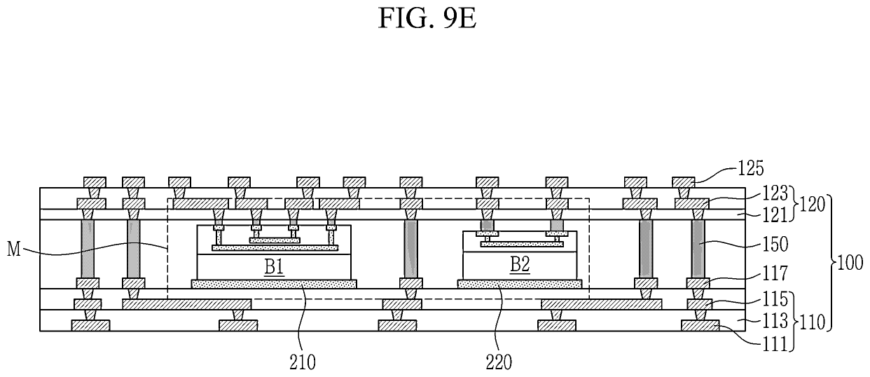

FIG. 9A to FIG. 9E illustrate a manufacturing method of a semiconductor package according to an example embodiment of the present disclosure.

In the present example embodiment, a manufacturing method of the semiconductor package 11 shown in FIG. 2 is disclosed as an example. However, those skilled in the art will understand that the semiconductor package 12 shown in FIG. 4, the semiconductor package 13 shown in FIG. 6, and the semiconductor package 14 shown in FIG. 8 may be manufactured through the same process.

Referring to FIG. 9A, the first redistribution layer 110 is provided, and the conductive posts 150 are provided on the upper surface of the first redistribution layer 110.

The first redistribution layer 110 and the conductive posts 150 may be formed using, for example, lithography and etching techniques, but may also be formed using other known techniques. Because these techniques are already known, detailed descriptions thereof will be omitted here.

Referring to FIG. 9B, the first bridge die B1 and the second bridge die B2 are attached to the upper surface of the first redistribution layer 110. The first bridge die B1 is attached on the upper surface of the first redistribution layer 110 by the first attachment film 210, and the second bridge die B2 is attached on the upper surface of the first redistribution layer 110 by the second attachment film 220.

The first bridge die B1 and the second bridge die B2 are manufactured by separate processes. The first bridge die B1 and the second bridge die B2 include the connection patterns formed by lithography and etching techniques, and the connection pads are exposed on the upper surfaces thereof. The conductive pillars are provided on the connection pads. The lower surfaces of the first bridge die B1 and the second bridge die B2 are silicon layers, and by grinding these silicon layers, the thickness of the first bridge die B1 and the thickness of the second bridge die B2 may be adjusted respectively. In the present example embodiment, the thickness of the first bridge die B1 is greater than the thickness of the second bridge die B2.

The first conductive pillars of the first bridge die B1 have a smaller pitch than the second conductive pillars of the second bridge die B2. Accordingly, the maximum height of the first conductive pillars is smaller than the maximum height of the second conductive pillars. However, since the upper surface of the first bridge die B1 is vertically higher than the upper surface of the second bridge die B2, the first conductive pillars and the second conductive pillars horizontally overlap each other in appropriate height ranges. Thereby, a sufficient margin is secured in the subsequent grinding process and the TTV risk is reduced.

Referring to FIG. 9C, all elements on the upper surface of the first redistribution layer 110 are molded by the mold material 450. In this state, for planarization by the subsequent grinding process, a grinding target height G must be set.

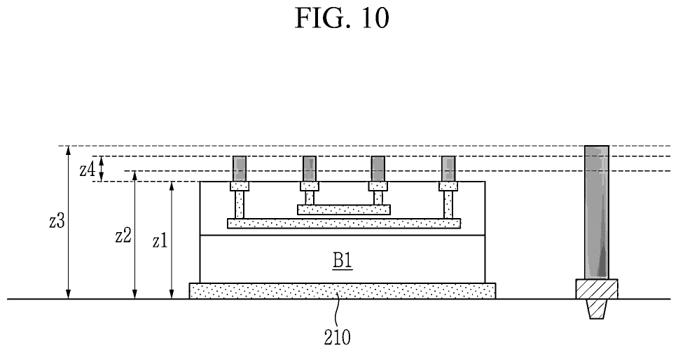

The setting of the grinding target height G will be described with reference to FIG. 10. FIG. 10 is an example for understanding, and example embodiments of the present disclosure are not limited thereto.

A distance from the upper surface of the first redistribution layer to the upper surface of the mold is indicated by z3. Although the upper end of the conductive post is shown in FIG. 10 as having the same height as the upper surface of the mold, the mold may generally cover the conductive post. That is, the upper surface of the mold may be disposed higher than the upper end of the conductive post.

A distance from the upper surface of the first redistribution layer to the upper surface of the first bridge die B1 is indicated by z1. z4 represents the maximum length of the first conductive pillars formed on the upper surface of the first bridge die B1. As described above, the grinding target height needs to be set at a position higher than the minimum length of the first conductive pillars considering the TTV of the first redistribution layer, the TTV generated by the grinding process, and the distribution of the conductive posts. In FIG. 10, z2 represents the grinding target height.

Although example embodiments are not limited thereto, in the example embodiment, when the thickness of the first attachment film is 10 μm, the thickness of the first bridge die B1 is 35 μm, and the maximum height of the first conductive pillars is 40 μm, the grinding target height z2 may be set at 60±10 μm from the upper surface of the first redistribution layer. In this case, z1 is 45 μm and z4 is 40 μm.

When the grinding target height is set, a grinding process is performed, as shown in FIG. 9D. Upper ends of the first conductive pillars, the second conductive pillars, and the conductive posts are exposed on the surface planarized by the grinding process.

Referring to FIG. 9E, the second redistribution layer 120 is formed. The second redistribution layer 120 includes a second insulating layer 121 and second redistribution patterns 123. The second redistribution patterns 123 are electrically connected to the first conductive pillars, the second conductive pillars, and the conductive posts. The second pad patterns 125 are formed on the second redistribution layer 120.

FIG. 9E illustrates the completed interposer 100. When a plurality of semiconductor chips are mounted on the interposer 100 and a bump array is provided on the lower surface of the interposer 100, the semiconductor package 11 shown in FIG. 2 is obtained.

While a manufacturing method of the semiconductor package 11 according to an example embodiment of the present disclosure has been described, a person skilled in the art may easily come up with manufacturing methods for the semiconductor packages 12, 13, and 14 according to other example embodiments with reference to the manufacturing method described above.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor package comprising:
a first redistribution layer;
a plurality of bridge dies on an upper surface of the first redistribution layer;
a second redistribution layer on the plurality of bridge dies and electrically connected to the plurality of bridge dies;
a plurality of conductive posts between the first redistribution layer and the second redistribution layer; and
a plurality of semiconductor chips on an upper surface of the second redistribution layer, wherein
each of the bridge dies includes connection pads on an upper surface of the bridge dies, and a pitch between first connection pads of a first bridge die among the plurality of bridge dies is smaller than a pitch between second connection pads of a second bridge die among the plurality of bridge dies, and
a distance between an upper surface of the first bridge die and a lower surface of the second redistribution layer is smaller than a distance between an upper surface of the second bridge die and the lower surface of the second redistribution layer.

2. The semiconductor package of claim 1, wherein
a thickness of the first bridge die is larger in a vertical direction than a thickness of the second bridge die.

3. The semiconductor package of claim 1, further comprising:
a first attachment film; and
a second attachment film, wherein
the first bridge die is connected to the upper surface of the first redistribution layer by the first attachment film,
the second bridge die is connected to the upper surface of the first redistribution layer by the second attachment film; and
a thickness of the first attachment film is greater than a thickness of the second attachment film.

4. The semiconductor package of claim 3, wherein
a thickness of the first bridge die in a vertical direction is smaller or equal to a thickness of the second bridge die in the vertical direction.

5. The semiconductor package of claim 1, further comprising:
solder bumps connecting the first bridge die to the upper surface of the first redistribution layer, and
an attachment film connecting the second bridge die to the upper surface of the first redistribution layer.

6. The semiconductor package of claim 1, further comprising:
first conductive pillars; and
second conductive pillars, wherein
the first connection pads of the first bridge die are electrically connected to the second redistribution layer through the first conductive pillars, and
the second connection pads of the second bridge die are electrically connected to the second redistribution layer through the second conductive pillars.

7. The semiconductor package of claim 6, wherein
a pitch between the first conductive pillars is less than a pitch between the second conductive pillars, and
a thickness of the first conductive pillars is less than a thickness of the second conductive pillars.

8. The semiconductor package of claim 7, wherein
the first bridge die includes a first connection layer and a first silicon layer,
the first connection layer includes the first connection pads and a first connection pattern connecting the first connection pads, and
a lower surface of the first silicon layer is on the upper surface of the first redistribution layer; and
the second bridge die includes a second connection layer and a second silicon layer,
the second connection layer includes the second connection pads and a second connection pattern connecting the second connection pads, and
a lower surface of the second silicon layer is on the upper surface of the first redistribution layer.

9. The semiconductor package of claim 1, wherein
the plurality of semiconductor chips include a first semiconductor chip, a second semiconductor chip, and a third semiconductor chip;
the first bridge die electrically connects the first semiconductor chip to the second semiconductor chip; and
the second bridge die electrically connects the second semiconductor chip to the third semiconductor chip.

10. The semiconductor package of claim 9, wherein
the first semiconductor chip and the second semiconductor chip are logic chips, and
the third semiconductor chip is a memory chip.

11. The semiconductor package of claim 10, wherein
the third semiconductor chip is a memory chip stack.

12. The semiconductor package of claim 9, wherein
the first bridge die partially overlaps both the first semiconductor chip and the second semiconductor chip in a plan view, and
the second bridge die partially overlaps both the second semiconductor chip and the third semiconductor chip in the plan view.

13. A semiconductor package comprising:
a first redistribution layer;
a first bridge die on an upper surface of the first redistribution layer;
a passive element on the upper surface of the first redistribution layer;
a second redistribution layer on the first bridge die and the passive element, the second redistribution layer being electrically connected to the bridge die and the passive element;
a plurality of conductive posts between the first redistribution layer and the second redistribution layer; and
a plurality of semiconductor chips on an upper surface of the second redistribution layer,
the first bridge die including connection pads on an upper surface of the first bridge die, and
the passive element including connection terminals on an upper surface of the passive element;
a pitch between first connection pads of the first bridge die is smaller than a pitch between the connection terminals of the passive element; and
a distance between the upper surface of the first bridge die and a lower surface of the second redistribution layer is smaller than a distance between the upper surface of the passive element and the lower surface of the second redistribution layer.

14. The semiconductor package of claim 13, further comprising:
first conductive pillars; and
second conductive pillars, wherein
the first connection pads of the first bridge die and the second redistribution layer are electrically connected by the first conductive pillars,
the connection terminals of the passive element and the second redistribution layer are electrically connected by the second conductive pillars,
a pitch between the first conductive pillars is less than pitch between the second conductive pillars, and
a thickness of the first conductive pillars is less than a pitch of the second conductive pillars.

15. The semiconductor package of claim 14, wherein
a thickness of the first bridge die is larger in a vertical direction than a thickness of the passive element.

16. The semiconductor package of claim 14, further comprising:
a first attachment film; and
a second attachment film, wherein
the first bridge die is connected to the upper surface of the first redistribution layer by the first attachment film, and the passive element is connected to the upper surface of the first redistribution layer by the second attachment film; and
a thickness of the first attachment film is greater than a thickness of the second attachment film.

17. The semiconductor package of claim 13, further comprising:
a second bridge die on the upper surface of the first redistribution layer, wherein
the second bridge die includes second connection pads on an upper surface of the second bridge die,
a pitch between the second connection pads is greater than a pitch between the first connection pads of the first bridge die and less than a pitch between the connection terminals of the passive element, and
a distance between the upper surface of the second bridge die and the lower surface of the second redistribution layer is greater than a distance between the upper surface of the first bridge die and the lower surface of the second redistribution layer, and
the distance between the upper surface of the second bridge die and the lower surface of the second redistribution layer is smaller than a distance between the upper surface of the passive element and the lower surface of the second redistribution layer.

18. A manufacturing method of a semiconductor package, comprising:
providing a first redistribution layer;
providing conductive posts on an upper surface of the first redistribution layer;
mounting a first bridge die and a second bridge die on the upper surface of the first redistribution layer, the first bridge die including first connection pads on an upper surface of the first bridge die and first conductive pillars on the first connection pads, the second bridge die including second connection pads on an upper surface of the second bridge die and second conductive pillars on the second connection pads, a pitch between the first conductive pillars being smaller than a pitch between the second conductive pillars, and the upper surface of the first bridge die being higher than the upper surface of the second bridge die in a vertical direction;
molding the conductive posts, the first bridge die, and the second bridge die with a mold material;
performing planarization by performing a grinding process on a structure including the mold material, the conductive posts, the first conductive pillars, and the second conductive pillars, the grinding process planarizing an upper surface of the structure to have a planarized surface at a grinding target height, the grinding target height being at a first distance above the upper surface of the first bridge die and at a second distance above the upper surface of the second bridge die, the second distance being greater than the first distance;
providing a second redistribution layer on the planarized surface of the structure; and
mounting a plurality of semiconductor chips on an upper surface of the second redistribution layer.

19. The manufacturing method of the semiconductor package of claim 18, wherein
a thickness of the first bridge die in a vertical direction is larger than a thickness of the second bridge die.

20. The manufacturing method of the semiconductor package of claim 18, wherein
the grinding target height is determined based on both an effective height range of the first conductive pillars according to a pitch between the first conductive pillars and an effective height range of the second conductive pillars according to a pitch between the second conductive pillars.
